(19) United States
(12) Patent Application Publication
(10) Pub. No.: US 2026/0276446 A1
(43) Pub. Date: Sep. 17, 2026

(54) OPTICAL SENSOR MODULE HAVING BAND-PASS FILTER AND PROCESS MONITORING SYSTEM HAVING THE SAME

(71) Applicant: KOREA INSTITUTE OF MACHINERY & MATERIALS, Daejeon (KR)

(72) Inventors: Jinyeong LEE, Daejeon (KR); Woo Seok KANG, Daejeon (KR); Mikyung LIM, Daejeon (KR); Seong-jae JEON, Daejeon (KR); Hyeon-Don KIM, Daejeon (KR); Kwangseop KIM, Daejeon (KR); Suwan JEON, Daejeon (KR); Min HUR, Daejeon (KR); Dae-Woong KIM, Seoul (KR); Minwoo KWEUN, Daejeon (KR)

(21) Appl. No.: 19/469,713

(22) PCT Filed: Feb. 22, 2024
(86) PCT No.: PCT/KR2024/002358

§ 371 Date: Sep. 26, 2025

(30) Foreign Application Priority Data
May 2, 2023 (KR) 10-2023-0057028
Oct. 18, 2023 (KR) 10-2023-0139355

(51) Int. Cl. G01J 3/443; H10P 72/00

(52) U.S. Cl. CPC G01J 3/443; H10P 72/0604

(57) ABSTRACT

In an optical sensor module having a band-pass filter and a process monitoring system having the optical sensor module, the optical sensor module includes an optical detecting part, a transmission filter part and a filter holder part. The optical detecting part has at least two optical detectors spaced apart from each other. The transmission filter part is disposed over the optical detecting part and has at least two transmission filters. The filter holder part is disposed over the optical detecting part, and the transmission filter part is mounted on the filter holder part. The transmission filters are spaced apart from each other and respectively disposed over the optical detectors. The transmission filters are disposed with different angles with respect to an incident light.

### BACKGROUND OF THE INVENTION

### Technical Field

Example embodiments of the present invention relate to an optical sensor module having a band-pass filter and a process monitoring system having the optical sensor module. More particularly, example embodiments of the present invention relate to an optical sensor module having a band-pass filter and a process monitoring system having the optical sensor module, capable of removing background signals effectively and detecting an end point of the process more accurately, in monitoring the process using plasma light emitted from a semiconductor or display manufacturing process, especially the process with a high aspect ratio and a low open ratio.

### Discussion of the Related Art

Plasma is used in various ways in the manufacturing process of semiconductors or displays, and in processes where such plasma is used, the status of the process may be monitored through sensing of light emitted from the plasma.

Furthermore, many spectroscopic sensors using band-pass filters are being used to monitor the process status.

In addition, in the case of the spectral sensor using the band-pass filter, a signal of relatively high intensity compared to signal acquisition noise and dark current noise may be obtained through photoelectron amplification by enlarging the area of the photodetector and applying high voltage. Thus, various kinds of technologies such as U.S. Pat. No. 8,817,267.

However, this band-pass filter type spectral sensor has a problem in that it is difficult to distinguish between a signal to be observed and a signal existing in the same wavelength band.

Thus, technology such as Korean laid-open patent No. 10-2023-0142267 is being developed to remove background signals from incident signals and obtain only the emission signals that are purely monitored. In Korean laid-open patent No. 10-2023-0142267, the technology for obtaining the pure emission signal through linear approximation is disclosed when the intensity change range for background signal and noise wavelength change is relatively small.

Here, in order to remove the background signal through this linear approximation, an ultra-narrow band transmission filter is required to selectively transmit only the emission optical signal band and the background signal band adjacent thereto. However, accurately manufacturing the ultra-narrow band transmission filter for the selected specific wavelength band has the problem of relatively high manufacturing difficulty.

### SUMMARY

Example embodiments of the present invention provide an optical sensor module having a band-pass filter, capable of removing background signals effectively and detecting an end point of the process more accurately, in monitoring the process using plasma light emitted from a semiconductor or display manufacturing process, especially the process with a high aspect ratio and a low open ratio.

In addition, example embodiments of the present invention also provide an optical sensor module having a band-pass filter, capable of removing background signals effectively by adjusting an inclination angle of the band-pass filter, without manufacturing band-pass filters for the optical signal wavelength to be monitored and the background signal wavelength separately.

In addition, example embodiments of the present invention also provide and a process monitoring system having the optical sensor module.

According to one aspect of the present invention, the optical sensor module includes an optical detecting part, a transmission filter part and a filter holder part. The optical detecting part has at least two optical detectors spaced apart from each other. The transmission filter part is disposed over the optical detecting part and has at least two transmission filters. The filter holder part is disposed over the optical detecting part, and the transmission filter part is mounted on the filter holder part. The transmission filters are spaced apart from each other and respectively disposed over the optical detectors. The transmission filters are disposed with different angles with respect to an incident light.

In an example embodiment, upper surfaces of the filter holder part may extend with inclined angles different from each other, and the transmission filters may be respectively mounted on the upper surfaces of the filter holder part.

In an example embodiment, a normal line of each of the transmission filters may form an acute angle with respect to the incident light.

According to one aspect of the present invention, the optical sensor module includes a module receiving part, a splitter, an optical detecting part and a transmission filter part. The module receiving part is configured to form a receiving space. An incident portion into which a light is incident is formed in a first side surface of the module receiving part. The splitter part is disposed in the receiving space, and has at least one splitter configured to split an incident light. The optical detecting part has optical detectors disposed at a second side surface and a third side surface. The second side surface faces the first side surface and the third side surface is adjacent to the first side surface. The transmission filter part is disposed between the splitter and the optical detector, and has transmission filters having inclined angles different from each other with respect to the optical detector.

In an example embodiment, each of the splitters may include an incident surface disposed toward the incident light, a first surface disposed toward the third side surface, and a second surface disposed toward the second side surface.

In an example embodiment, the transmission filter part may include a first transmission filter extending parallel with the third side surface, a second transmission filter inclined with respect to the second side surface by a predetermined angle.

In an example embodiment, the splitter part may include a plurality of splitters arranged along a direction of the incident light.

In an example embodiment, the transmission filter part may include a plurality of first transmission filters inclined with respect to the third side surface, and a plurality of second transmission filters extending parallel with the second side surface.

In an example embodiment, angles of the first transmission filters with respect to the third side surface may be different from each other. An angle of each of the first transmission filter with respect to the third side surface may be an acute angle.

In an example embodiment, the optical detecting part may include a plurality of first optical detectors spaced apart from each other on the third side surface, in the same number as the number of the splitters, and a single second optical detector disposed on the second side surface regardless of the number of the splitters.

According to one aspect of the present invention, a process monitoring system has the optical sensor module mentioned above. Among the transmission filters, the transmission filter having a first inclined angle transmits an emission optical signal in an emission optical signal band, and the transmission filter having a second inclined angle transmits a background signal in a background signal band. The process monitoring system includes a signal processor configured to calculate a pure emission optical signal in which the background signal is removed, based on the emission optical signal and the background signal.

In an example embodiment, the first and second inclined angles may be determined to be changed with each other, according to the emission optical signal band and the background signal band.

According to one aspect of the present invention, an optical sensor module includes a module receiving part, a splitter part, a transmission filter part and an optical detecting part. The module receiving part is configured to form a receiving space, and an incident portion into which a light is incident is formed in a first side surface of the module receiving part. The splitter part is disposed in the receiving space, and has at least one splitter configured to split an incident light. The transmission filter part has at least two transmission filters arranged along a direction perpendicular to a direction of the incident light, and the transmission filters is configured to transmit predetermined signals of different bands. The optical detecting part has at least two optical detectors respectively arranged with the transmission filters, and the optical detectors is configured to detect a light passing through the transmission filters.

In an example embodiment, the transmission filters may be spaced apart from each other, a full width at half maximum (FWHM) of each of the transmission filters may be 10 nm or less, and a size of each of the transmission filters may be larger than that of each of the optical detectors.

In an example embodiment, the splitter part may include a first splitter receiving the incident light, and at least one additional splitter receiving a light split from the first splitter.

In an example embodiment, the first splitter may be disposed at a first side of the module receiving part to be aligned with the incident light. The additional splitter may be spaced apart from the first splitter by a predetermined distance and may be arranged along an arranged direction of the transmission filters.

In an example embodiment, as the light is split and provided from the first splitter to the additional splitter, an amount of the light incident into each of the transmission filters may be changed.

In an example embodiment, the first splitter may be disposed at a center of the module receiving part to be arranged with the incident light. The additional splitter may be spaced apart from the first splitter along a direction of the incident light, and at least two additional splitters may be arranged to be perpendicular to the direction of the incident light.

In an example embodiment, the additional splitters may be respectively arranged with the transmission filters, and an amount of the light incident into each of the transmission filters from each of the additional splitters may be uniformly maintained.

According to one aspect of the present invention, a process monitoring system has the optical sensor module mentioned above. Each of the transmission filters transmitting signals in different bands is configured to transmit an emission optical signal in an emission optical signal band and a background signal in a background signal band. The process monitoring system includes a signal processor configured to calculate a pure emission optical signal in which the background signal is removed, based on the emission optical signal and the background signal.

According to example embodiments of the present invention, conventionally, in order to extract only the pure emission optical signal excluding the background signal from the conventional emission optical signal, it was necessary to detect the signals of the emission optical signal band and the background signal band, respectively. However, the production of a conventional ultra-narrow band transmission filter for this purpose had limitations in the production process.

Thus, according the present example embodiments, transmission filters arranged adjacent to each other form different angles with respect to an incident light, that is, the normal lines of the transmission filters form different angles with the incident light. Then, optical signals of various bands may be detected through a single incident light, and accurate and easy detection of pure emission optical signals may be performed by merely removing signals in the background signal band.

By forming the transmission filters to have different inclination angles so that they are spaced apart from each other, accurate detection of pure emission optical signals may be performed while omitting the production of ultra-narrow band transmission filters. Then, the manufacturing process of the optical sensor module may be easy, and signal processing for optical signal detection may also be easily performed.

Here, the transmission filters may be arranged continuously in one direction and spaced apart from each other, but alternatively, they may be arranged at different positions in a predetermined storage space.

A splitter unit is provided to split the incident light and provide it to two planes perpendicular to each other, so that the light is split and provided in a plurality of directions. Then, the transmission filters that transmit each branched light are formed so that the angle of inclination, that is, the angle of the normal, with respect to the incident light is different from that of the incident light. Thus, signals of different frequency bands may be detected from the single light. In addition, by removing the background signal from the signals detected in this way, the pure emission optical signal may be easily detected with a simple calculation.

In particular, by separating and providing light in directions perpendicular to each other through branching as described above, signal overlap or interference between the transmission filter that transmits the optical signal in the emission optical signal band and the transmission filter that transmits the background signal in the background signal band may be minimized. Thus, the accuracy of the detected optical signal may be further improved.

In addition, along one side of the module storage unit, a plurality of transmission filters may be arranged to be spaced apart from each other to form different angles, and splitters to provide light may also be arranged to be spaced apart from each other. Thus, signals of various transmission bands may be detected according to various incidence angle changes, and filtering of background signals may be implemented more accurately.

Furthermore, considering the band of the emitted optical signal or the band of the background signal, the tilt angle formed by the transmission filters may be determined in various ways, so that emitted optical signals may be optimally detected in accordance with the characteristics of various processes. Then, the efficiency and accuracy of process monitoring may be improved.

In addition, regarding plasma light emitted from semiconductor or display manufacturing processes that use plasma, especially processes with high aspect ratio and low open ratio, the end point of the process may be detected more accurately by implementing a high signal-to-noise ratio (SNR). In particular, an optical signal is detected by aligning transmission filters that transmit signals of a preset band and optical detectors that are aligned with the optical detectors that detect the corresponding light, so that detection accuracy may be improved while minimizing the increase in sensor size caused by using a large-area photodetector as in the prior art.

Here, the transmission filters and light detectors may be replaced and installed depending on the characteristics of the plasma light, so that a detection system with the optimal band may be performed according to various plasma usage environments. In addition, the transmission filters are spaced at a predetermined distance, and the size of the transmission filter is made larger than the size of the photo detector, so that signal interference due to alignment error between the transmission filter and photodetector may be minimized.

In addition, a splitter unit that splits light is located in front of the transmission filters, so that the problem of reduced spatial resolution caused by monitoring multiple signals may be solved.

The problem of spatial resolution deterioration may be solved by splitting the light generated from the plasma light source into light incident on each transmission filter through the splitter unit. Here, although signal reduction may occur due to the distribution of light, this may be solved by applying the transmission filters to a large area and each transmitting signals of a specific band.

In addition, the splitters included in the splitter unit are arranged in various ways, so that the signal-to-noise ratio (SNR) of signals in individual wavelength bands may be controlled in various ways.

### BRIEF DESCRIPTION OF THE DRAWINGS

FIG. 1A is a graph showing an intensity of an emission signal according to a wavelength and a filter transmission rate in an optical sensor module, and FIG. 1B is a graph showing a state of detecting a transmission optical signal and a transmission background signal of FIG. 1A;

FIG. 2A is a perspective view illustrating an optical sensor module according to an example embodiment of the present invention, and FIG. 2B is a side view illustrating the optical sensor module of FIG. 2A;

FIG. 3 is a graph showing a wavelength change according to a filter incident angle of an optical signal in the optical sensor module of FIG. 2A;

FIG. 4A is a perspective view illustrating an optical sensor module according to another example embodiment of the present invention, and FIG. 4B is a plan view illustrating the optical sensor module of FIG. 4A;

FIG. 5 is a graph showing a method of obtaining an intensity of an emission signal and a filter transmission rate, using the wavelength change according to a filter incident angel of an optical signal, in a process monitoring system having the optical sensor module of FIG. 4A.

FIG. 6 is a graph showing a method of detecting a transmission optical signal and a transmission background signal, using the process monitoring system having the optical sensor module of FIG. 4A;

FIG. 7A is a perspective view illustrating an optical sensor module according to still another example embodiment of the present invention, and FIG. 7B is a plan view illustrating the optical sensor module of FIG. 7A;

FIG. 8 is a schematic view illustrating an optical sensor module according to still another example embodiment of the present invention;

FIG. 9 is a schematic view illustrating an optical sensor module according to still another example embodiment of the present invention;

FIG. 10 is a schematic view illustrating an optical sensor module according to still another example embodiment of the present invention;

FIG. 11A and FIG. 11B are graphs showing plasma monitoring results in an etching process using a conventional diffraction-based spectrometer;

FIG. 12 is a graph showing characteristics of a transmission filter part and an emission optical signal applied to the process monitoring system of the present example embodiment; and FIG. 13A and FIG. 13B are graphs showing plasma monitoring results in an etching process using the process monitoring system according to the present example embodiment to which the transmission filter part of FIG. 12 is applied.

<Reference numerals>

| | |
|---|---|
| 10, 11, 12, 13, 100, 101: optical sensor module | |
| 1: light source | 2: light |
| 4: incident light | 5: split light |
| 6: analysis light | 20: base part |
| 30, 500, 501, 1400: optical detecting part | |
| 31, 32, 33, 510, 520, 530, 511, 521, 1401, 1402, 1403: optical detector | |
| 40: filter holder part | 41, 42, 43: filter holder |
| 50, 400, 401, 1300: transmission filter part | |
| 51, 52, 53, 410, 420, 430, 411, 421, 1301, 1302, 1303: transmission filter | |
| 200, 201: module receiving part | 211, 212: incident portion |
| 250, 251, 252: window part | |
| 300, 301, 1500, 1510: splitter part | |
| 310, 320, 1501, 1502, 1503, 1504, 1511, 1512, 1513: splitter | |
| 600: signal processor | |

### DETAILED DESCRIPTION OF THE INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

Here, before explaining the example embodiments of the present invention, an example of detecting a transmission optical signal and a transmission background signal in an optical sensor module will be described.

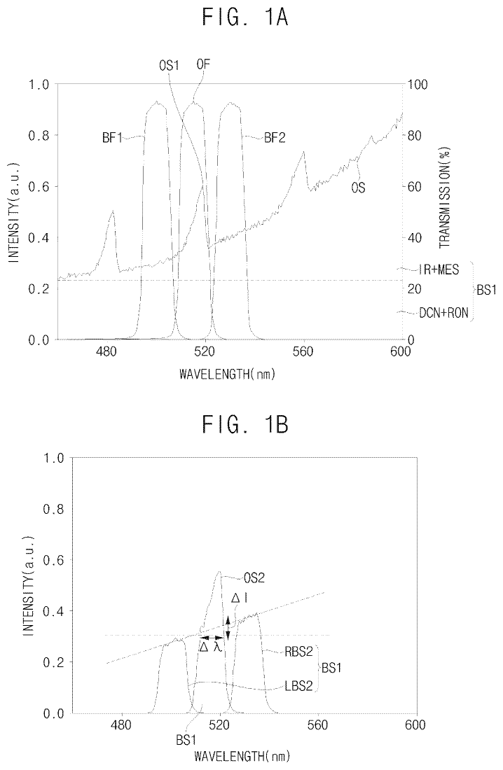

FIG. 1A is a graph showing an intensity of an emission signal according to a wavelength and a filter transmission rate in an optical sensor module, and FIG. 1B is a graph showing a state of detecting a transmission optical signal and a transmission background signal of FIG. 1A.

The optical sensor module explained below monitors a process state based on a plasma optical signal generated in a plasma using process among semiconductor or display manufacturing processes such as an etching process. Various kinds of process information such as an end of the process may be obtained, by monitoring the optical signal of the process using the optical sensor module.

For example, when the optical sensor module having transmission filters transmitting the signals in different wavelength bands on an emission signal OS emitted in the above-mentioned plasma process is used, a pure emission optical signal which finally needs to be detected may be extracted.

The plasma emission signal is discontinuous with respect to the wavelength, and a background signal such as a molecular emission signal MES and an infrared heater signal IR, a dark current DCN and a signal acquisition noise RON are continuous with respect to the wavelength. Thus, using the above characteristics of the signals, the signals except for the pure emission optical signal may be effectively removed.

As illustrated in FIG. 1A, a band-pass filter OF selectively transmitting only an atomic emission signal OS1 to be observed, and band-pass filters BF1 and BF2 selectively transmitting wavelength bands adjacent to the signal OS1 are used. Then, the signal BS1 of the sum of the plasma emission signal, the background signal and the noise is obtained, and the signal LBS2 and RBS2 of the overlapping signal of the background signal and the noise is obtained.

Here, when the intensity change width ΔI with respect to the wavelength change Δλ of the background signal and the noise is relatively small, the following equation (1) is satisfied through a linear approximation.

$${BS}_{1} = \frac{1}{2} ( {LBS}_{2} + {RBS}_{2} ) \qquad Equation ( 1 )$$

Here, a calculation is performed between signals whose corresponding bands have been transmitted through the band-pass filters OF, BF1 and BF2. Then, among the wavelength band signals OS1 of the plasma emission signal to be observed, only the pure emission signal OS2 from which the background signal has been removed may be obtained.

For more detailed information about the acquisition of the pure emission signal using the band-pass filters of FIG. 1A and FIG. 1B, Korean Patent Application No. 10-2022-0041282 (filed on Apr. 1, 2022) may be referred.

Accordingly, among the signals included in the plasma emission signal OS, acquiring only the pure emission signal excluding the background signal may be performed through the band-pass filters filtering the signals in different bands and the calculation for the corresponding signals. Finally, it is necessary to accurately implement the band-pass filters that may filter the signals in different bands.

Accordingly, the example embodiments of the present invention relate to an optical sensor module that accurately implements the band-pass filters for only obtaining the pure emission signal from the above plasma emission signal, and a process monitoring system having the optical sensor module. Hereinafter, it will be described in detail with reference to the drawings.

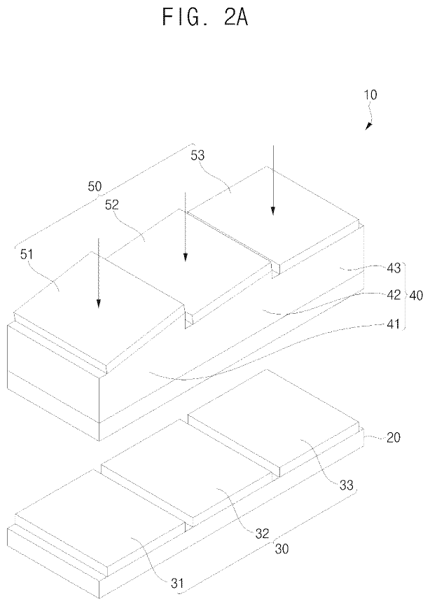

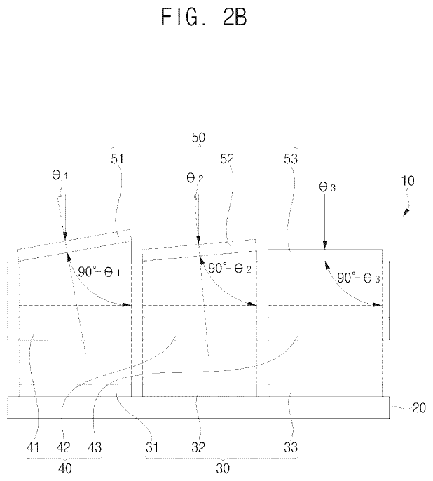

FIG. 2A is a perspective view illustrating an optical sensor module according to an example embodiment of the present invention, and FIG. 2B is a side view illustrating the optical sensor module of FIG. 2A.

Referring to FIG. 2A and FIG. 2B, the optical sensor module 10 according to the present example embodiment includes a base part 20, an optical detecting part 30, a filter holder part 40 and a transmission filter part 50.

The base part 20 has a plate shape extending along a direction with a predetermined area, as illustrated in the figure, and forms a base on which the optical detecting part 30 is mounted.

The optical detecting part 30 is formed on the base part 20, and includes a plurality of optical detectors 31, 32 and 33 detecting the light. Each of the optical detectors 31, 32, 33 has the same structure and shape, and the optical detectors 31, 32, 33 are spaced apart from each other by a predetermined distance.

For example, each of the optical detectors 31, 32, 33 may have a rectangular shape with a predetermined area, and the distance between the optical detectors 31, 32 and 33 may be smaller than the area of each of the optical detectors 31, 32 and 33.

Here, the area of each of the optical detectors 31, 32 and 33, and the distance between the optical detectors may be changed variously. The area may be designed considering the area of the transmission filter part 50 explained below, and in the case of the distance, any separation distance sufficient to prevent interference or overlap when receiving signals of different wavelength bands is sufficient.

Each of the optical detectors 31, 32 and 33 detects the signals filtered by transmitting the transmission filters of the transmission filter part 50 explained below. The signal detected by each of the optical detectors is the signal with different wavelength bands.

Here, the optical detectors are illustrated to be three optical detectors arranged in a line, but not limited thereto and thus two or at least four optical detectors may be arranged in a line

Alternatively, a plurality of the optical detectors may be arranged in a matrix shape, and two or more rows and columns are sufficient in a matrix array and various combinations may be possible.

Accordingly, as the number and the arrangement of the optical detectors are changed, the number and the arrangement of the filter holder part 40 and the transmission filter part 50 may be changed. However, for the convenience of explanation, hereinafter, the optical detectors are three, and the number and the arrangement of the filter holder part and the transmission filter part are assumed to be formed to correspond to the optical detectors.

The filter holder part 40 is an integrally formed structure disposed over the optical detecting part 30, and the filter holder part 40b may have a rectangular block shape extending in a line as a whole.

The optical detectors 31, 32 and 33 are spaced apart from each other, but the filter holder part 40 is the integrally formed structure.

Here, the filter holder part 40 is a fixing structure fixing the transmission filter part 50 mounted on an upper surface of the filter holder part 40. A lower surface of the filter holder part 40 forms a plane shape extending parallel with an extending direction of the base part 20.

The filter holder part 40 may have a predetermined height or thickness, and the upper surface of the filter holder par 40 forms a plurality of inclined surfaces on which the transmission filter part 50 is mounted, unlike the lower surface of the filter holder part 40 extending parallel with the base part 20.

The upper surface of the filter holder part 40 includes the surfaces divided in the same number as the number of the optical detectors 31, 32 and 33, and the surfaces form angles different from each other as illustrated in the figure.

Thus, transmission filters 51, 52 and 53 of the transmission filter part 50 are respectively mounted on the surfaces of the filter holder part 40 forming the different angles.

Each of the transmission filters 51, 52 and 53 has the same area and has a plate shape, but an inclined angle of each of the transmission filters 51, 52 and 53 is different.

As illustrated in the figure, when the light is vertically incident into the optical sensor module 10 from a light emission device such as a plasma device PS, a normal direction of each of the transmission filters 51, 52 and 53 forms the different angle with respect to the incident light.

For example, a normal direction of the first transmission filter 51 may form a first angle θ₁ with respect to the incident light, a normal direction of the second transmission filter 52 may form a second angle θ₂ with respect to the incident light, and a normal direction of the third transmission filter 53 may form a third angle θ₃ with respect to the incident light.

The first to third angles may be θ₁, θ₂, and θ₃ are respectively defined as incident angles of the lights incident into the first to third transmission filters 51, 52 and 53.

Among the first to third angles, the following equation (2) may be satisfied.

$$90 ° > {θ}_{1} > {θ}_{2} > {θ}_{3} \geq 0 ° \qquad Equation ( 2 )$$

Here, the first to third angles are different from each other. Each of the first and second angles may be an acute angle, and the third angle may be an acute angle more than 0°. Here, when the third angle is 0°, the third transmission filter 53 has a plane shape extending perpendicular to the incident light.

Accordingly, each of the first to third transmission filters 51, 52 and 53 has the different angle with respect to the incident light, and transmits the different band of signal for the incident light.

Thus, the light passing through each of the first to third transmission filters 51, 52 and 53 is detected at each of the first to third optical detectors 31, 32 and 33.

Then, a signal processor explained below performs a predetermined calculation on the signals having the different bands of wavelength as explained in FIG. 1A and FIG. 1B, and then the pure emission optical signal may be obtained.

The detailed explanation on this is explained below.

For example, each of the first to third transmission filters 51, 52 and 53 may include a band-pass filter based on Brag Reflector. Each of the first to third transmission filters 51, 52 and 53 is an ultra-narrow band transmission filter with a narrow transmission width at half maximum FWHM of several nm or less in a visible light band, and may be performed as a brag mirror having a resonance layer. The structure of each of the first to third transmission filters may be manufactured by alternately stacking heterogeneous thin films with different refractive indices to a thickness of several tens of nm.

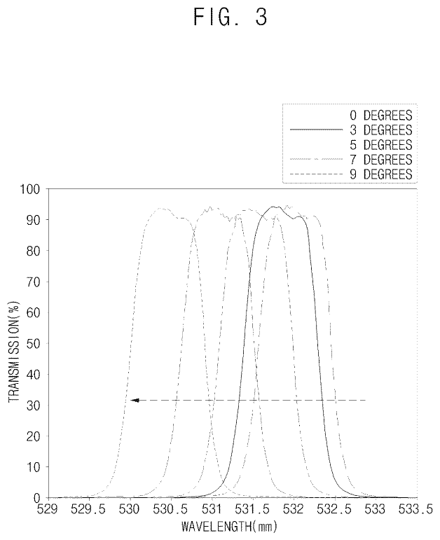

FIG. 3 is a graph showing a wavelength change according to a filter incident angle of an optical signal in the optical sensor module of FIG. 2A.

For the optical sensor module 10 of FIG. 2B, as the inclined angles θ₁, θ₂, and θ₃ of the transmission filters 51, 52 and 53 changes, the wavelength of the transmitted light also changes, and the change of the transmission wavelength is shown in FIG. 3.

As explained above, each of the first to third transmission filters 51, 52 and 53 is the band-pass filter based on Brag Reflector, and the relationship between a filter incident angle of the light and a wavelength of a transmission center is defined as Equation (3).

$${λ}_{θ} = {{λ}_{0} [ 1 - \frac{{n}_{0}}{{n}_{*}} {sin}^{2} θ ]}^{1 / 2} \qquad Equation ( 3 )$$

Here, λ_{θ} is the wavelength of the transmission center of the transmission filter which is formed to be inclined, λ₀ is a the wavelength of the transmission center for vertically incident optical signal, n₀ is the refractive index of an air, n* is the refractive index of the transmission filter, and θ is an incident angle of the optical signal passing through the transmission filter.

Finally, the wavelength λ_{θ} of the transmission center of the transmission filter moves toward a shorter wavelength compared to the designed wavelength, and this may be confirmed in FIG. 3.

Using these characteristics, the wavelength of the transmitted optical signal is determined to transmit the optical signal in the band that requires transmission, by forming the inclination angle of the first to third transmission filters 51, 52 and 53 variously.

When the inclination angles of the first to third transmission filters 51, 52 and 53 are formed based on the pure emission optical signal band and the background signal band in the emission light in the plasma process, as explained referring to FIG. 1A and FIG. 1B, the pure emission optical signal may be detected from the emission light based on the optical signals of each detected band.

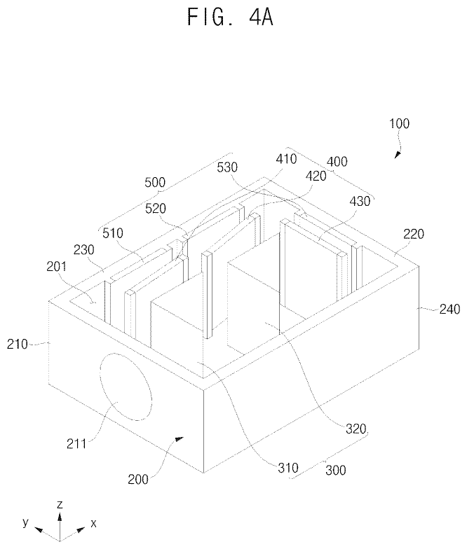

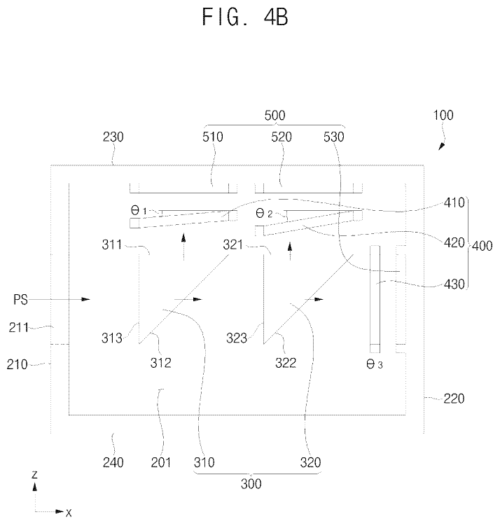

FIG. 4A is a perspective view illustrating an optical sensor module according to another example embodiment of the present invention, and FIG. 4B is a plan view illustrating the optical sensor module of FIG. 4A.

The optical sensor module 100 according to the present example embodiment is structurally different from the optical sensor module 10 of FIG. 2A and FIG. 2B, such as the arrangement of the optical detecting part and the transmission filter part, and additional inclusion of a splitter part. However, The optical sensor module 100 according to the present example embodiment is the same as the optical sensor module 10 of FIG. 2A and FIG. 2B, in the configuration of changing the inclination angle of the transmission filters in consideration of the band of the transmitted signal and finally detecting the pure emission optical signal through this. Thus, the structure and the arrangement of the optical sensor module 100 are detailed explained below.

Referring to FIG. 4A and FIG. 4B, the optical sensor module 100 according to the present example embodiment includes a module receiving part 200, a splitter part 300, a transmission filter part 400 and an optical detecting part 500.

As illustrated in the figure, the module receiving part 200 has a rectangular frame shape, and includes first and second side surfaces 210 and 220 facing each other along a first direction X and third and fourth side surfaces 230 and 240 facing each other along a second direction Y perpendicular to the first direction X. A predetermined receiving space 202 is formed inside of the module receiving part 200 by the first to fourth side surfaces 210, 220, 230 and 240.

Here, an upper portion of the module receiving part 200 is illustrated to be open, but this is for explain an inside of the module receiving part 200. Thus, the upper portion of the module receiving part 200 is enclosed and the inside of the module receiving part 200 is enclosed.

An incident portion 211 into which the emitted light from the plasma device PS is incident is formed at the first side surface 210 of the module receiving part 200, and the incident portion 211 may include a transparent window.

The first side surface 21 is the structure directly attached to a visible window of the plasma device, and the incident portion 211 may be the visible window of the plasma device.

The splitter part 300 is received by the receiving space 202, and includes first and second splitters 310 and 320 sequentially arranged along the first direction X.

In the present example embodiment, the splitter part 300 includes two splitters, but not limited thereto, and 3 or more splitters may be sequentially arranged along the first direction X.

Accordingly, the number of the splitters along the first direction X which is the direction of the incident light maybe sufficient to be 2 or more, and the number thereof is not limited. Further, when three or more splitters are disposed, the number of the optical detectors and the number of the transmission filters may be the same number as that of the splitters.

However, hereinafter for the convenience of explanation, it will be explained that two splitters 310 and 320 are arranged along the first direction X.

Each of the splitters 310 and 320 has a prism shape, and the inclination surface of each of the splitters 310 and 320 is arranged to be inclined with an incident direction of the incident light.

A first surface 311 of the first splitter 310 extends parallel with the first direction X, an incident surface 313 of the first splitter 310 extends parallel with the second direction Y, and a second surface 312 of the first splitter 310 is inclined with respect to an incident direction of the incident light. For example, the second surface 312 is inclined with respect to the first direction which is the incident direction of the incident light, by about 45°.

In addition, the second splitter 320 is disposed to be spaced apart from the first splitter 310 at a rear side of the first splitter 310 along the incident direction of the light, and the arrangement of a first surface 321, a second surface 322 and an incident surface 323 is substantially same as that of the first splitter 310. For example, the first surface 321 of the second splitter 320 is parallel with the first direction X, the incident surface 323 thereof is parallel with the second direction Y, and the second surface 322 thereof is inclined with respect to the first direction X by about 45°.

Accordingly, as the first and second splitters 310 and 320 are sequentially arranged, the emitted light incident into the incident portion 211 is split continuously as an arrow of FIG. 4B.

The light incident into the incident portion 211 is split by the first splitter 310, to be provided into the first transmission filter 410 through the first surface 311 and to be provided into the incident surface 323 of the second splitter 320 through the second surface 312.

In addition, the light incident into the incident surface 323 of the second splitter 320 is split by the second splitter 320, to be provided into the second transmission filter 420 through the first surface 321 and to be provided into the third transmission filter 430 through the second surface 322.

Accordingly, the incident light is split and is provided to the transmission filters through the splitters.

The optical detecting part 500 detects the optical signal passing through the transmission filter part 400, and is substantially same as the optical detecting part 30 of FIG. 2A except for the disposition and arrangement of the optical detection part 500.

As illustrated in the figure, the optical detecting part 500 includes first to third optical detectors 510, 520 and 530. The first and second optical detectors 510 and 520 are disposed on the third side surface 230 and are spaced apart from each other, and the third optical detector 530 is disposed on the second side surface 220.

The areas of the first to third optical detectors 510, 520 and 530 are the same with each other.

As the third optical detector 530 is fixed and disposed on the second side surface 220, the third optical detector 530 detects the optical signal when the light passing through the incident portion 211 of the first side surface 210 merely passes through the first and second splitters 310 and 320. Here, the signal transmitted in a predetermined band by the third transmission filter 430 is detected.

Alternatively, the first optical detector 510 is fixed and disposed on the third side surface 230, and faces and is parallel with the first surface 311 of the first splitter 310.

Then, as the light incident into the incident portion 211 is split by the first splitter 310 and is provided into the first surface 311, the first optical detector 510 detects the signal. Here, the signal transmitted in a predetermined band by the first transmission filter 410 is detected.

The second optical detector 520 is fixed on the third surface 230 and is spaced apart from the first optical detector 510. The second optical detector 520 faces and is parallel with the first surface 321 of the second splitter 320.

Then, as the light split through the second surface 312 of the first splitter 310 is split again by the second splitter 320 and then is provided to the first surface 323, the second optical detector 520 detects the signal. Here, the signal transmitted in a predetermined band by the second transmission filter 420 is detected.

The transmission filter part 400 transmits a signal of a predetermined band, and includes the first to third transmission filters 410, 420 and 430. Here, the functions of the first to third transmission filters 410, 420 and 430 are substantially same as those of the first to third transmission filters 51, 52 and 53 of FIG. 2A.

The first transmission filter 410 is disposed between the first surface 311 of the first splitter 310 and the first optical detector 510, and is inclined with respect to the first direction X which is parallel with the first surface 311 and the third side surface 230 by a first angle θ₁.

Thus, a normal direction of the first transmission filter 410 forms the first angle θ₁ with an incident direction of the light passing through the first surface 311.

In addition, the second transmission filter 420 is disposed between the first surface 321 of the second splitter 320 and the second optical detector 520, and is inclined with respect to the first direction X which is parallel with the first surface 321 and the third side surface 230 by a second angle θ₂.

Thus, a normal direction of the second transmission filter 420 forms the second angle θ₂ with an incident direction of the light passing through the first surface 321.

Further, the third transmission filter 430 is disposed between the second surface 322 of the second splitter 320 and the third optical detector 530, is parallel with the second side surface 220 and is along the second direction Y. The third transmission filter 430 is not inclined with the second side surface 220.

Thus, a normal direction of the third transmission filter 430 forms a third angle θ₃ with an incident direction of the light passing through the second surface 322, but here, the third angle θ₃ may be 0°.

Alternatively, the third angle θ₃ may not be 0°.

The first to third angles θ₁, θ₂ and θ₃ may satisfy Equation (4) below. However, Equation (4) may be an example relationship, and if each angle satisfies an acute angle of 0° or more, the condition for forming different sizes is satisfied, and the size relationship between them may be changed in various ways.

$$90 ° > {θ}_{2} > {θ}_{1} > {θ}_{3} \geq 0 ° \qquad Equation ( 4 )$$

Accordingly, as the first to third transmission filters 410, 420 and 430 are disposed with the angles different from each other, the first to third transmission filters 410, 420 and 430 transmit the wavelengths of different bands and thus the pure emission optical signal may be obtained finally.

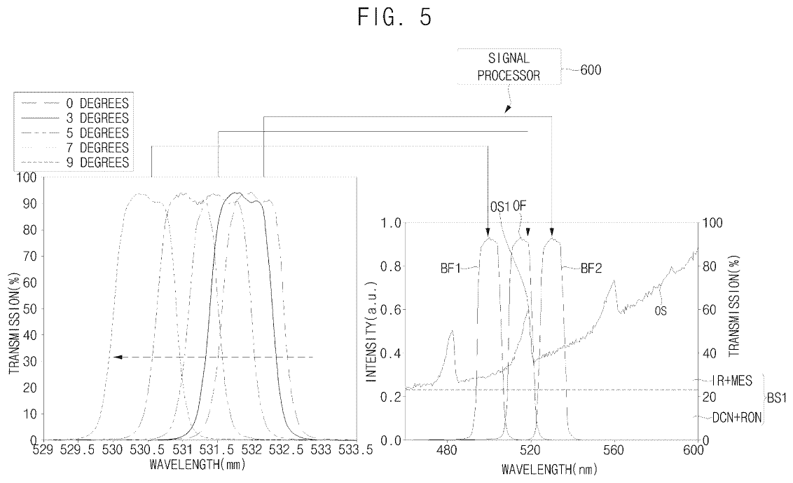

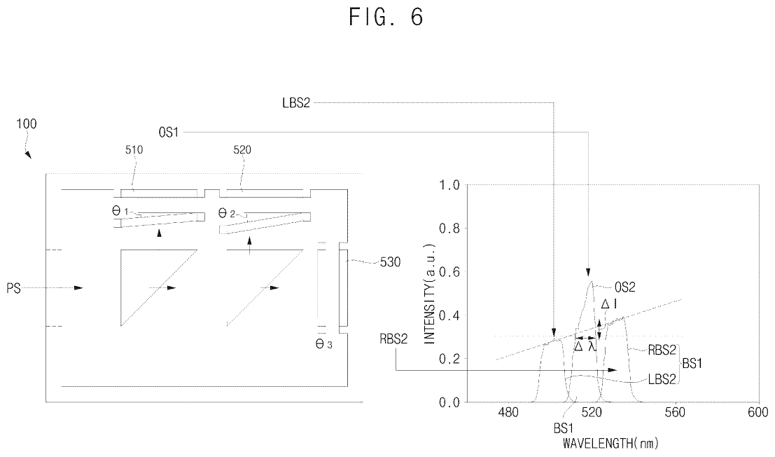

FIG. 5 is a graph showing a method of obtaining an intensity of an emission signal and a filter transmission rate, using the wavelength change according to a filter incident angel of an optical signal, in a process monitoring system having the optical sensor module of FIG. 4A. FIG. 6 is a graph showing a method of detecting a transmission optical signal and a transmission background signal, using the process monitoring system having the optical sensor module of FIG. 4A.

Referring to FIG. 5, the process monitoring system having the optical sensor module 100 further includes a signal processor 600. The signal process part 600 performs the signal processing as explained referring to FIG. 1A and FIG. 1B, and then the pure emission optical signal is obtained.

When the third angle θ₃ of the third transmission filter 430 is preset to be 0°, the first angle θ₁ of the first transmission filter 410 is preset to be 5°, and the second angle θ₂ of the second transmission filter 420 is preset to be 9° in the optical sensor module 100 of FIG. 4A, the signal of different wavelength bands are detected by the first to third optical detectors 510, 520 and 530.

For example, the third transmission filter 430 having the third angle θ₃ is the background signal transmission filter BF2, and then the signal in the background signal wavelength band is transmitted and the background signal is detected by the third optical detector 530.

In addition, the first transmission filter 410 having the first angle θ₁ is the band-pass filter OF selectively transmitting the atomic emission signal OS1, and then the atomic emission signal is transmitted and the atomic emission signal is detected by the first optical detector 510.

Further, the second transmission filter 420 having the second angle θ₂ is the background transmission filter BF1, and then the signal in the background signal wavelength band with a different wavelength is transmitted and the different wavelength background signal is detected by the second optical detector 520.

Thus, as illustrated in FIG. 6, in the optical sensor module 100 at which the first to third angles θ₁, θ₂ and θ₃ (=0°) satisfy Equation (4), when the splitter part 300 is designed to have ½ incident on the observation target optical signal wavelength band OF and ¼ incident on the background signal wavelength bands BF1 and BF2, the signal processor 600 obtains the pure emission optical signal in which the background signals are removed based on the signals detected by the first to third optical detectors 510, 520 and 530.

Here, the signal processor 600 may obtain the pure emission optical signal via a simple arithmetic calculation (OS2−(½) (LBS2+RBS2)) between the signals detected by the optical detectors.

Accordingly, as the transmission filters 410, 420 and 430 of the transmission filter part 400 are disposed to be inclined with the incident light and the inclined angle of each of the transmission filters 410, 420 and 430 are variously changed, the signals in the different bands may be detected and the information on the pure emission optical signal except for the background signal may be easily obtained.

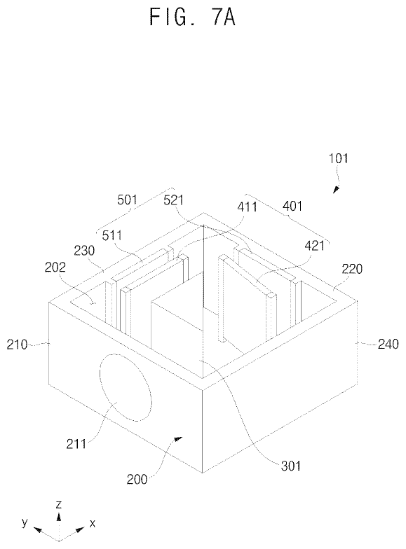

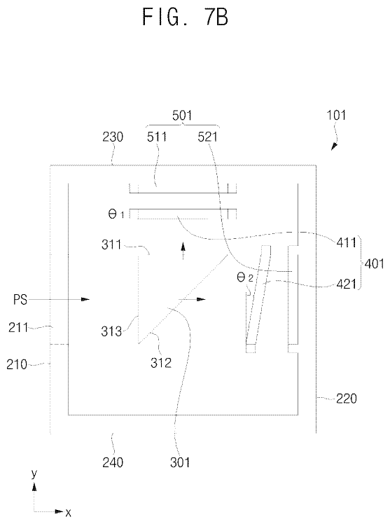

FIG. 7A is a perspective view illustrating an optical sensor module according to still another example embodiment of the present invention, and FIG. 7B is a plan view illustrating the optical sensor module of FIG. 7A.

The optical sensor module 200 according to the present example embodiment is substantially same as the optical sensor module 100 of FIG. 4A and FIG. 4B, except for the number of the splitters and the number and arrangement of the optical detectors and transmission filters, and thus the same reference numerals are used for the same elements and any repetitive explanation will be omitted.

Referring to FIG. 7A and FIG. 7B, the optical sensor module 200 according to the present example embodiment includes a module receiving part 200, a splitter part 301, a transmission filter part 401 and an optical detecting part 501.

The module receiving part 200 is substantially same as that in FIG. 6A, but only one splitter is configured and the size of the receiving space 202 may be smaller.

The splitter part 301 includes a single splitter, and as explained above, the splitter 301 includes a first surface 311 extending along the first direction X, an incident surface 313 extending along the second direction Y, and a second surface 312 inclined by 45° with respect to the first direction X.

Thus, the light incident into the incident portion 211 is incident into the incident surface 313 and then is split by the splitter 301. Then, the light is provided toward a first transmission filter 411 through the first surface 311, and is also provided toward a second transmission filter 421 through the second surface 312.

The optical detecting part 501 includes a first optical detector 511 fixed at the third side surface 230 and a second optical detector 521 fixed at the second side surface 220.

Here, the first and second optical detectors 511 and 521 detect the signals with different bands, and the detected signals are operated by the signal processor 600 to be obtained as the pure emission optical signal as explained above.

The transmission filter part 401 includes the first transmission filter 411 disposed between the first optical detector 511 and the first surface 311, and the second transmission filter 421 disposed between the second optical detector 521 and the second surface 312.

Here, the first transmission filter 411 is disposed between the first surface 311 of the splitter 301 and the first optical detector 511, and is inclined by a first angle θ₁ with respect to the first direction X which is parallel with the first surface 311 and the third side surface 230.

Then, a normal direction of the first transmission filter 411 forms the first angle θ₁ with respect to the incident direction of the light transmitting the first surface 311, and the first angle θ₁ may be 0°.

Alternatively, the first angle θ₁ formed by the first transmission filter 411 may not be 0°.

The second transmission filter 421 is disposed between the second surface 312 of the splitter part 301 and the second optical detector 521, and is inclined by a second angle θ₂ with respect to the second direction Y which is parallel with the second side surface 220.

Then, a normal direction of the second transmission filter 421 forms the second angle θ₂ with respect to the incident direction of the light transmitting the second surface 321, and the second angle θ₂ may be an acute angle.

The normal direction of the second transmission filter 421 forms the second angle θ₂ with respect to the incident direction of the light passing through the second surface 312.

In the present example embodiment, the first and second angles θ₁ and θ₂ may satisfy Equation (5). The relationship in Equation (5) below is only an example, and if each angle satisfies an acute angle of 0° or more, it satisfies the condition that the sizes are different from each other, and the size relationship between them may be varied in various ways.

$$90 ° > {θ}_{2} > {θ}_{1} \geq 0 ° \qquad Equation ( 5 )$$

Accordingly, as the first and second transmission filters 411 and 421 are disposed with having different angles, the first and second transmission filters 411 and 421 transmit the wavelengths with different bands, and thus the pure emission optical signal may be obtained finally. The obtainment of the pure emission optical signal is performed by the signal processor 600, and the detailed calculation is the same as explained above referring to FIG. 5 and FIG. 6.

The optical sensor module 200 according to the present example embodiment, transmits the signals with different wavelength bands using two transmission filters. Thus, the optical sensor module 200 may be applied when the intensity of the background signal is relatively weak compared to the intensity of the emission optical signal, in the signal emitted from the process to be measured.

When the background signal in the band surrounding the emission optical signal is relatively weak, the background signal is effectively removed by the single transmission filter and then the pure emission optical signal may be effectively obtained.

In the same way, when the intensity of the background signal is relatively strong compared to the intensity of the emission optical signal, it is necessary to acquire signals in multiple channels by increasing the number of transmission filters.

To performing this, four or more channels may be required in addition to the three channels as in FIG. 4A and FIG. 4B, and thus three or more splitters, three or more transmission filters and three or more optical detectors may be configured in a similar arrangement to the arrangement as explained above.

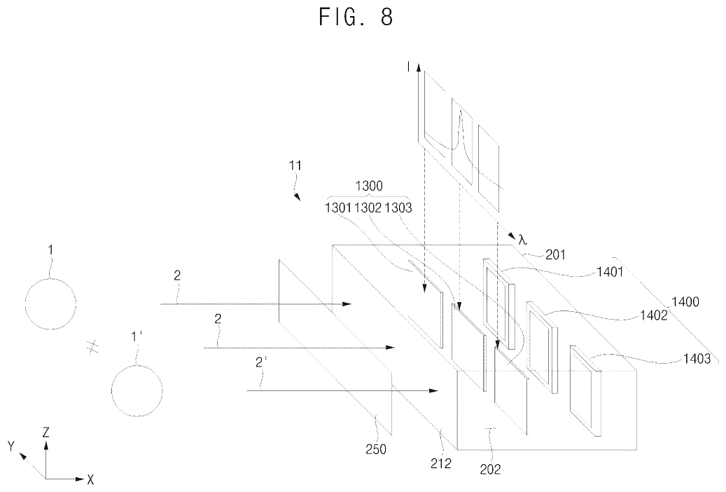

FIG. 8 is a schematic view illustrating an optical sensor module according to still another example embodiment of the present invention.

Referring to FIG. 8, the optical sensor module 11 according to the present example embodiment includes a module receiving part 201, a window part 250, a transmission filter part 1300 and an optical detecting part 1400.

The module receiving part 201 may have a block shape forming a predetermined inner space 202, and includes an incident portion 212 toward a light source 1. The window part 250 is formed at the incident portion 212. Here, the window part 250 may be omitted and a light 2 may be directly incident into the incident portion 212. However, in the example embodiments below, the light 2 is incident into the incident portion 212 through the window part 250.

The transmission filter part 1300 and the optical detecting part 1400 are received in the inner space 202 of the module receiving part 201, and although not shown in the figure, a mounting part on which the transmission filter part 1300 is mounted and a mounting part on which the optical detecting part 1400 is mounted may be formed by partitioning in the inner space 202.

The transmission filter part 1300 and the optical detecting part 1400 are respectively mounted in the areas divided into predetermined areas in the inner space 202, and the mounted structures of the transmission filter part 1300 and the optical detecting part 1400 may be variously designed.

For example, the transmission filter part 1300 and the optical detecting part 1400 may be mounted on the mounting parts formed like slits, or may be mounted on the mounting parts at which separate fixing members are configured.

Further, the transmission filter part 1300 and the optical detecting part 1400 may be detached from the inner space 202 of the module receiving part 201 and may be removed externally, and any other transmission filter part or optical detecting part may be selectively mounted. That is, the transmission filter part 1300 and the optical detecting part 1400 may be selectively attached to and detached from the module receiving part 201, and thus optimal transmission filter part and optical detecting part may be selectively mounted considering the characteristics of the light 2 to be detected.

The window part 250 includes a transparent material, and the light 2 generated from the light source 1 is provided into the module receiving part 201 through the window part 250.

Here, the incident portion 212 of the module receiving part 201 is positioned to face the light 2, and the incident portion 212 is also open like a window. Thus, the light 2 passing through the window part 250 is incident into the inner space 202 through the incident portion 212.

In FIG. 8, the window part 250 is spaced apart from the incident portion 212, but FIG. 8 is illustrated to explain the structure of the window part 250 and the window part 250 is substantially attached to the incident portion 212.

In addition, in the present example embodiment, the window part 250 is formed on an entire surface of the incident portion 212, and thus the light 2 passing through the window part 250 is uniformly incident into the transmission filters of the transmission filter part 1300 disposed inside of the module receiving part 201.

The transmission filter part 1300 includes a plurality of transmission filters 1301, 1302 and 1303 disposed along a direction perpendicular to a direction of the incident light (first direction X), and each of the transmission filters has a predetermined area.

Each of the transmission filters 1301, 1302 and 1303 is formed along a direction parallel with an YZ plane which is perpendicular to the first direction X, and the area of each of the transmission filters 1301, 1302 and 1303 is the same.

Here, in FIG. 8, three transmission filters are illustrated, but the number thereof is not limited thereto, and two transmission filters or four or more transmission filters may be configured.

The transmission filters 1301, 1302 and 1303 are arranged along the second direction Y perpendicular to the first direction X, and are spaced apart from each other along the second direction Y by a predetermined distance.

Here, each of the transmission filters 1301, 1302 and 1303 transmits the signal of a predetermined band for the incident light 2, and the transmitting bands of the transmission filters 1301, 1302 and 1303 may be predetermined to be different from each other.

The transmission filters 1301, 1302 and 1303 may be selectively mounted considering the characteristics of the plasma light 2, so that each of the transmission filters may be selected to transmit the light signal having the predetermined band and then may be mounted on the module receiving part 201, considering the characteristics of the plasma process.

Accordingly, the transmission filters should be selected to transmit the light having the predetermined band considering the characteristics of the plasma process. Thus, the transmission band width of the transmission filter should be wider than the half width of the signal to be observed, to enhance signal-to-noise ratio as the amount of gain increases. However, the transmission band width thereof should be limited not to include signals in surrounding wavelength bands which are not to be observed.

Here, the full width at half maximum FWHM of each of the transmission filters is 10 nm or less. The FWHM may be determined considering the bands of atomic (>1 nm) and molecular (~10 nm) emission signals present in the plasma and considering the characteristics of the plasma light 2 generated in the plasma process.

The optical detecting part 1400 is disposed at a rear side of the transmission filter part 1300 along the path of the light 2, that is the first direction X. As explained above, the optical detecting part 1400 is detachably positioned at a certain mounting part of the inner space 202.

Here, the optical detecting part 1400 includes a plurality of optical detectors 1401, 1402 and 1403, and each of the optical detectors 1401, 1402 and 1403 is aligned with each of the transmission filters 1301, 1302 and 1303 along the first direction X.

Thus, each of the optical detectors 1401, 1402 and 1403 has a shape similar to each of the transmission filters 1301, 1302 and 1303, such as a rectangular plate shape, and the optical detectors 1401, 1402 and 1403 are spaced apart from each other by a predetermined distance along the second direction Y.

Thus, each of the optical detectors 1401, 1402 and 1403 detects the optical signal having a predetermined band transmitting each of the transmission filters 1301, 1302 and 1303. Here, each of the optical detectors 1401, 1402 and 1403 may have an area of 10⁻¹~10² mm². The area of each optical detector may be determined considering photon flux in the wavelength band of the signal of the light 2.

In addition, each of the optical detectors 1401, 1402 and 1403 may include a photo diode, an avalanche photodiode, a multi pixel photon counter (MPPC) and so on, and these may be selected considering the need for signal amplification.

In addition, as explained above, the transmission filters 1301, 1302 and 1303 are spaced apart from each other along the second direction Y, to minimize the signal interference due to the alignment error between the transmission filter and the optical detector. Here, to minimize the signal interference, the side of each of the optical detectors 1401, 1402 and 1403 may be smaller than that of each of the transmission filters 1301, 1302 and 1303.

The transmission filters 1301, 1302 and 1303 have the same size or area with each other, and the optical detectors 1401, 1402 and 1403 have the same size or area with each other. However, the size or the area of each of the transmission filters is larger than that of each of the optical detectors, and the signal interference may be minimized.

As explained above, the process monitoring system having the optical sensor module 11 further includes a signal processor, although not shown in the figure. The signal processor performs the signal processing based on the signals detected by the optical detectors 1401, 1402 and 1403 in the same way as explained above.

Although not shown in the figure, the signal processor is disposed at a rear side of the optical detecting part 1400 along the path of the light 2, that is the first direction X. The signal processor may be positioned in the inner space 202 of the module receiving part 201 or may be positioned at an outside of the module receiving part 201.

The signal processor processes the optical signal detected by the optical detecting part 1400 into the optical signals for monitoring, and for example, may include a signal integrator, a signal converter and a signal operator.

The signal integrator integrates the detected optical signal by setting an exposure time or integration time for each individual signal and the signal converter performs A/D conversion on the integrated signal to remove noise included in the signal. The signal calculator removes the background signal from the converted and noise-removed signal, thereby finally leaving only the optical signal that needs to be monitored in relation to the process conditions in the plasma process.

Accordingly, the optical signal of the monitoring target is transmitted, and through this, information about the process conditions or process status of the plasma process, which is the monitoring target process, may be obtained. Here, the obtained information may include various process information used in the process, such as the start of the process, the type of gas used in the process, and the end of the process, as described above.

For example, each of the transmission filters 1301, 1302 and 1303 transmits the signal having different band, and then an emission optical signal in the emission optical signal band and a background signal in the background signal band may be received through each of the transmission filters. In addition, the signals may be detected by each of the optical detectors 1401, 1402 and 1403.

Thus, the signal processor performs the signal processing as explained referring to FIG. 1A and FIG. 1B, and then calculates or obtains the pure emission optical signal in which the background signal is removed based on the emission optical signal and the background signal.

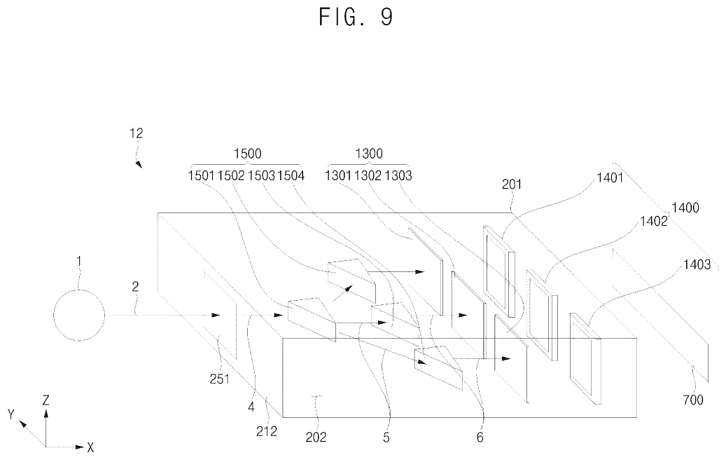

FIG. 9 is a schematic view illustrating an optical sensor module according to still another example embodiment of the present invention.

The optical sensor module 12 according to the present example embodiment is substantially same as the optical sensor module 11 of FIG. 8, except for a splitter part 1500 between the window part 251 and the transmission filter part 1300, and thus the same reference numerals are used for the same elements and any repetitive explanation will be omitted.

In the optical sensor module 11 of FIG. 8, as the area of the transmission filter and the optical detector increase, the light source 1 and 1′ incident into the adjacent transmission filter and the adjacent optical detector may be changed, and thus the signal of the light 2 and 2′ may also be changed.

Thus, in the optical sensor module 12 according to the present example embodiment, the problem due to the change of the light source and the signal of the light may be solved.

Referring to FIG. 9, the optical sensor module 12 further includes the splitter part 1500.

In the optical sensor module 11 of FIG. 8, multiple optical signals are detected by performing the transmission filter for each band, and thus multiple optical signals are monitored at the same time, and the transmission filter and the optical detector having relatively larger area or size are used for performing this.

As the area of the transmission filter or the optical detector becomes larger and simultaneous monitoring of multiple signals is performed, the problem of reducing spatial resolution may be caused. As the signals of similar wavelength bands are monitored within a predetermined space using a single monitoring device, the problem may occur in which the spatial resolution for distinguishing these signals from each other is deteriorated.

Accordingly, in the present example embodiment, the problem of the spatial resolution deterioration may be minimized by interposing the splitter part 1500.

In the present example embodiment, the splitter part 1500 is disposed in the inner space 202, and is disposed between the incident portion 212 and the transmission filter part 1300.

The splitter part 1500 may be detachably mounted on the mounting part which is formed at the inner space 202, like the transmission filter part 1300 and the optical detecting part 1400 as explained above.

As illustrated in FIG. 9, the splitter part 1500 includes a first splitter 1501 disposed adjacent to the incident portion 212, and additional splitters 502, 503 and 504 disposed between the first splitter 1501 and the transmission filter part 1300.

Here, as illustrated in the figure, the first splitter 1501 may be disposed at a center of the incident portion 121, and the incident light 4 is incident into the first splitter 1501.

The window part 251 is formed at a central area of the incident portion 212, and thus the light 2 from the light source 1 is incident into the window part 251 of the incident portion 212. Thus, the light 2 is incident into the inner space 202 only passing through the center of the incident portion 212.

Here, the first splitter 1501 is aligned with the window part 251 along the first direction X, and thus the incident light 4 passing through the window part 251 is only incident into the first splitter 1501.

Here, the additional splitters 1502, 1503 and 1504 are disposed at a rear side of the first splitter 1501 along the first direction X. In the present example embodiment, the additional splitters 1502, 1503 and 1504 may be aligned with the transmission filters 1301, 1302 and 1303, and thus three additional splitters are respectively aligned with the transmission filters along the first direction X, as illustrated in the figure.

Accordingly, a split light 5 provided through the first splitter 1501 is provided to each of the transmission filters 1301, 1302 and 1303 through each of the additional splitters 1502, 1503 and 1504. Thus, each of the transmission filters 1301, 1302 and 1303 and each of the optical detectors 1401, 1402 and 1403 performs the detection on the optical signal having the predetermined band.

When the incident light 4 is uniformly split by the first splitter 1501 and then is provided to the additional splitters 1502, 1503 and 1504, an analysis light 6 incident into the transmission filters 1301, 1302 and 1303 through the additional splitters 1502, 1503 and 1504 may be the light having the same amount of light 700.

In addition, in FIG. 9, the number of the additional splitters 1502, 1503 and 1504 is the same as that of the transmission filters and thus the additional splitters 1502, 1503 and 1504 are respectively aligned with the transmission filters, but the number of the additional splitters should not be the same as that of the transmission filters and the additional splitters should not be respectively aligned with the transmission filters.

That is, when the light split by the first splitter 1501 is incident into each of the transmission filters 1301, 1302 and 1303 with the same amount of the light, the number of the additional splitters 1502, 1503 and 1504 is not limited.

The process monitoring system having the optical sensor module 12 according to the present example embodiment may include the signal processor. When the signal processor processes the signal, as explained above, the signal processor obtains or calculates the pure emission optical signal in which the background signal is removed based on the emission optical signal and the background signal.

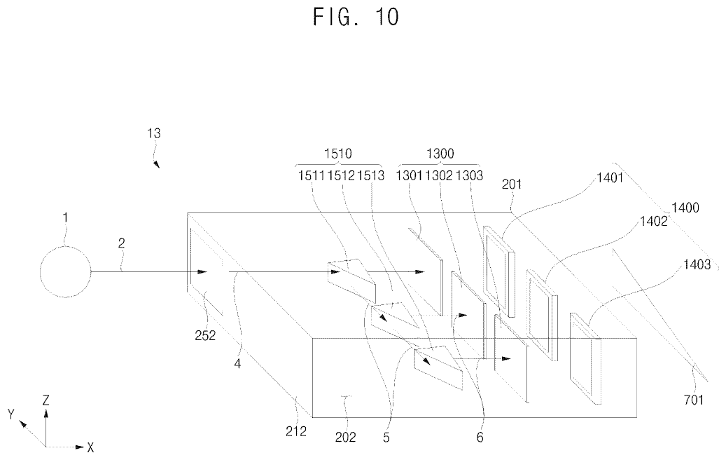

FIG. 10 is a schematic view illustrating an optical sensor module according to still another example embodiment of the present invention.

The optical sensor module 13 according to the present example embodiment is substantially same as the optical sensor module 12 of FIG. 9, except for dispositions of a splitter part 1510 and a window part 252, and thus the same reference numerals are used for the same elements and any repetitive explanation will be omitted.

Referring to FIG. 10, in the optical sensor module 13 according to the present example embodiment, the window part 252 is disposed at a first side of the incident portion 212. Thus, the light 2 emitted from the light source 1 is incident into a first side area in which the window part 252 is formed in the incident portion 212.

Here, the splitter part 1510 includes a first splitter 1511 and additional splitters 1512 and 1513, and the first splitter 1511 is disposed to be aligned with the window part 252 along the first direction X.

The first splitter 1511 is also disposed at the first side of the inner space 202, so that the incident light 4 incident into the first side of the incident portion 212 is incident into the first splitter 1511. For example, the first splitter 1511 may be disposed to be aligned with the first transmission filter 1301 along the first direction X.

Accordingly, the incident light 4 incident into the window part 252 is incident into the first splitter 1511, and the light is split by the first splitter 1511 and then is provided to the additional splitters 1512 and 1513.

As illustrated in the figure, the additional splitters 1512 and 1513 are arranged with the first splitter 1511 along the second direction Y, and the first splitter 1511 and the additional splitters 1512 and 1513 are spaced apart from each other by a predetermined distance along the second direction Y. Thus, as the first splitter 1511 is aligned with the first transmission filter 1301 along the first direction X, the additional splitters 1512 and 1513 are respectively aligned with the second and third transmission filters 1302 and 1302 along the first direction X.

Thus, the analysis light 6 passing through the first splitter 1511 is provided to the first transmission filter 1301, and the analysis light 6 passing through the additional splitters 1512 and 1513 is respectively provided to the second and third transmission filters 1302 and 1303. Thus, as explained above, each of the transmission filters 1301, 1302 and 1303 and each of the optical detectors 1401, 1402 and 1403 detects the optical signal with a predetermined band.

In the present example embodiment, the incident light 4 is split by the first splitter 1511 and then is provided to the additional splitters 1512 and 1513 sequentially, and thus an amount 701 of the analysis light 6 may be decreased from the first transmission filter 1301 toward the third transmission filter 1303.

The analysis light 6 having the light quantity different from each other is provided to each transmission filter that transmits the signal with different band, so that the signal-to-noise ratio (SNR) may be controlled differently for each individual wavelength band signal.

Further, in FIG. 10, the incident light 4 is illustrated o be provided to the first splitter 1511, but the window part 252 may be aligned with one of the additional splitters 1512 and 1513, and thus the incident light 4 may be incident into one of the additional splitters 1512 and 1513.

Accordingly, when the incident light 4 is incident into one of the additional splitters 1512 and 1513, the splitter into which the incident light 4 is incident functions as the first splitter and splits the light and then the split light may be provided to the other splitters. Thus, the amount of the analysis light 6 provided to each transmission filter may be controlled to be different.

The process monitoring system having the optical sensor module 13 according to the present example embodiment may include the signal processor. When the signal processor processes the signal, as explained above, the signal processor obtains or calculates the pure emission optical signal in which the background signal is removed based on the emission optical signal and the background signal.

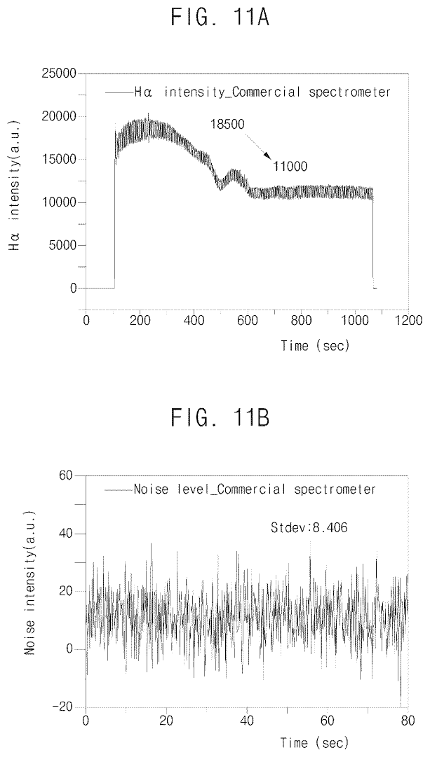

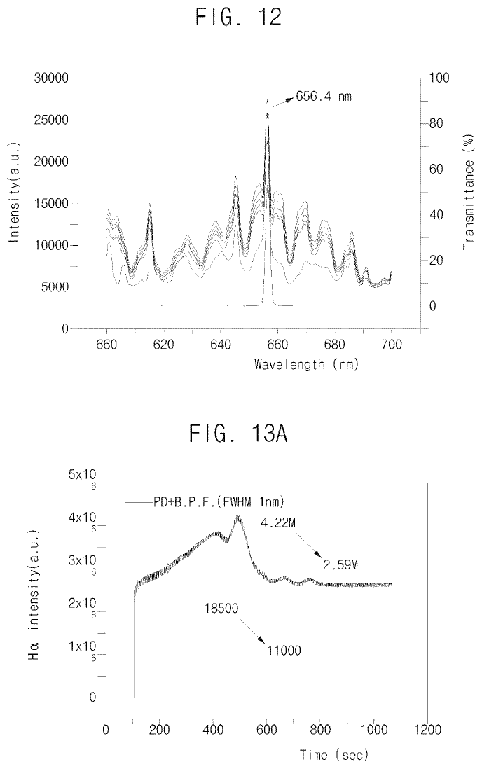

FIG. 11A and FIG. 11B are graphs showing plasma monitoring results in an etching process using a conventional diffraction-based spectrometer.

Referring to FIG. 11A and FIG. 11B, the results of monitoring plasma in an actual etching process using a conventional diffraction-based spectrometer are illustrated. FIG. 11A and FIG. 11B show the result of monitoring the plasma light generated in etching with 80 mTorr and 700 seconds, with providing carbon tetrafluoride (CF₄) and oxygen (O₂) at 20 sccm and 80 sccm respectively, when etching a polyimide layer having a depth of 2.7 μm. Here, the optical detector of a commercial diffraction-based spectrometer has a measuring area of 50×50 μm² for each wavelength.

FIG. 11A shows a change of an intensity of the optical signal (Ha intensity) detected in the etching process, and FIG. 11B shows a change of a noise intensity detected in the etching process.

Thus, based on FIG. 11A and FIG. 11B, when the conventional optical detector is used, the calculation results of signal-to-noise ratio (SNR) may be about 2200 based on the below calculation.

$$SNR ( conventional technology ) = \frac{18500}{8.406} ≃ 2200$$

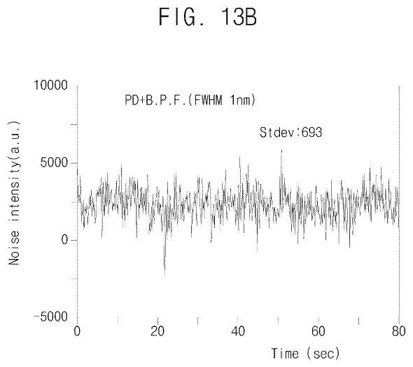

FIG. 12 is a graph showing characteristics of a transmission filter part and an emission optical signal applied to the process monitoring system of the present example embodiment. FIG. 13A and FIG. 13B are graphs showing plasma monitoring results in an etching process using the process monitoring system according to the present example embodiment to which the transmission filter part of FIG. 12 is applied.

FIG. 13A and FIG. 13B shows the results of the plasma monitoring using the optical sensor module 11 according to the previous example embodiment of FIG. 8, in etching with the same conditions of FIG. 11A and FIG. 11B explained above.

Here, the transmission filter part 1300 mounted on the optical sensor module 11 of FIG. 8 is determined to transmit the predetermined band of signal as in FIG. 12A.

In addition, in the optical sensor module 11, the area of each of the transmission filters has an area of 1×1 mm² and the area of the optical detectors also has an area of 1×1 mm². The full width at half maximum (FWHM) of the transmission filter is set to be 1 nm.

FIG. 13A shows the change of the intensity of the optical signal (Ha intensity) detected in the etching process, and FIG. 13B shows the change of a noise intensity detected in the etching process.

Thus, based on FIG. 13A and FIG. 13B, when the optical detector 11 according to the previous example embodiment of FIG. 8 is used, the calculation results of signal-to-noise ratio (SNR) may be about 6060 based on the below calculation.

$$SNR ( example embodiment ) = \frac{4.22 M}{693} ≃ 6060$$

Accordingly, more increased signal-to-noise (SNR) may be performed when using the optical sensor module 11 according to the previous example embodiment of FIG. 8, compared to the conventional technology.

According to example embodiments of the present invention, conventionally, in order to extract only the pure emission optical signal excluding the background signal from the conventional emission optical signal, it was necessary to detect the signals of the emission optical signal band and the background signal band, respectively. However, the production of a conventional ultra-narrow band transmission filter for this purpose had limitations in the production process.

Thus, according the present example embodiments, transmission filters arranged adjacent to each other form different angles with respect to an incident light, that is, the normal lines of the transmission filters form different angles with the incident light. Then, optical signals of various bands may be detected through a single incident light, and accurate and easy detection of pure emission optical signals may be performed by merely removing signals in the background signal band.

By forming the transmission filters to have different inclination angles so that they are spaced apart from each other, accurate detection of pure emission optical signals may be performed while omitting the production of ultra-narrow band transmission filters. Then, the manufacturing process of the optical sensor module may be easy, and signal processing for optical signal detection may also be easily performed.

Here, the transmission filters may be arranged continuously in one direction and spaced apart from each other, but alternatively, they may be arranged at different positions in a predetermined storage space.

A splitter unit is provided to split the incident light and provide it to two planes perpendicular to each other, so that the light is split and provided in a plurality of directions. Then, the transmission filters that transmit each branched light are formed so that the angle of inclination, that is, the angle of the normal, with respect to the incident light is different from that of the incident light. Thus, signals of different frequency bands may be detected from the single light. In addition, by removing the background signal from the signals detected in this way, the pure emission optical signal may be easily detected with a simple calculation.

In particular, by separating and providing light in directions perpendicular to each other through branching as described above, signal overlap or interference between the transmission filter that transmits the optical signal in the emission optical signal band and the transmission filter that transmits the background signal in the background signal band may be minimized. Thus, the accuracy of the detected optical signal may be further improved.

In addition, along one side of the module storage unit, a plurality of transmission filters may be arranged to be spaced apart from each other to form different angles, and splitters to provide light may also be arranged to be spaced apart from each other. Thus, signals of various transmission bands may be detected according to various incidence angle changes, and filtering of background signals may be implemented more accurately.

Furthermore, considering the band of the emitted optical signal or the band of the background signal, the tilt angle formed by the transmission filters may be determined in various ways, so that emitted optical signals may be optimally detected in accordance with the characteristics of various processes. Then, the efficiency and accuracy of process monitoring may be improved.

In addition, regarding plasma light emitted from semiconductor or display manufacturing processes that use plasma, especially processes with high aspect ratio and low open ratio, the end point of the process may be detected more accurately by implementing a high signal-to-noise ratio (SNR). In particular, an optical signal is detected by aligning transmission filters that transmit signals of a preset band and optical detectors that are aligned with the optical detectors that detect the corresponding light, so that detection accuracy may be improved while minimizing the increase in sensor size caused by using a large-area photodetector as in the prior art.

Here, the transmission filters and light detectors may be replaced and installed depending on the characteristics of the plasma light, so that a detection system with the optimal band may be performed according to various plasma usage environments. In addition, the transmission filters are spaced at a predetermined distance, and the size of the transmission filter is made larger than the size of the photo detector, so that signal interference due to alignment error between the transmission filter and photodetector may be minimized.

In addition, a splitter unit that splits light is located in front of the transmission filters, so that the problem of reduced spatial resolution caused by monitoring multiple signals may be solved.

The problem of spatial resolution deterioration may be solved by splitting the light generated from the plasma light source into light incident on each transmission filter through the splitter unit. Here, although signal reduction may occur due to the distribution of light, this may be solved by applying the transmission filters to a large area and each transmitting signals of a specific band.

In addition, the splitters included in the splitter unit are arranged in various ways, so that the signal-to-noise ratio (SNR) of signals in individual wavelength bands may be controlled in various ways.

Having described example embodiments of the present invention, it is further noted that it is readily apparent to those of reasonable skill in the art that various modifications may be made without departing from the spirit and scope of the invention which is defined by the metes and bounds of the appended claims.

1. An optical sensor module comprising:
an optical detecting part having at least two optical detectors spaced apart from each other;
a transmission filter part disposed over the optical detecting part and having at least two transmission filters; and
a filter holder part disposed over the optical detecting part, the transmission filter part being mounted on the filter holder part,
wherein the transmission filters are spaced apart from each other and respectively disposed over the optical detectors,
wherein the transmission filters are disposed with different angles with respect to an incident light.

2. The optical sensor module of claim 1, wherein upper surfaces of the filter holder part extend with inclined angles different from each other, and the transmission filters are respectively mounted on the upper surfaces of the filter holder part.

3. The optical sensor module of claim 2, wherein a normal line of each of the transmission filters forms an acute angle with respect to the incident light.

4. An optical sensor module comprising:
a module receiving part configured to form a receiving space, an incident portion into which a light is incident being formed in a first side surface of the module receiving part;
a splitter part disposed in the receiving space, and having at least one splitter configured to split an incident light;
an optical detecting part having optical detectors disposed at a second side surface and a third side surface, the second side surface facing the first side surface, the third side surface being adjacent to the first side surface; and
a transmission filter part disposed between the splitter and the optical detector, and having transmission filters having inclined angles different from each other with respect to the optical detector.

5. The optical sensor module of claim 4, wherein each of the splitters comprises:
an incident surface disposed toward the incident light;
a first surface disposed toward the third side surface; and
a second surface disposed toward the second side surface.

6. The optical sensor module of claim 5, wherein the transmission filter part comprises:
a first transmission filter extending parallel with the third side surface;
a second transmission filter inclined with respect to the second side surface by a predetermined angle.

7. The optical sensor module of claim 5, wherein the splitter part comprises a plurality of splitters arranged along a direction of the incident light.

8. The optical sensor module of claim 7, wherein the transmission filter part comprises:
a plurality of first transmission filters inclined with respect to the third side surface; and
a plurality of second transmission filters extending parallel with the second side surface.

9. The optical sensor module of claim 8, wherein angles of the first transmission filters with respect to the third side surface are different from each other,
wherein an angle of each of the first transmission filter with respect to the third side surface is an acute angle.

10. The optical sensor module of claim 7, wherein the optical detecting part comprises:
a plurality of first optical detectors spaced apart from each other on the third side surface, in the same number as the number of the splitters; and
a single second optical detector disposed on the second side surface regardless of the number of the splitters.

11. A process monitoring system having the optical sensor module of claim 1,
wherein among the transmission filters, the transmission filter having a first inclined angle transmits an emission optical signal in an emission optical signal band, and the transmission filter having a second inclined angle transmits a background signal in a background signal band,
wherein the process monitoring system comprises a signal processor configured to calculate a pure emission optical signal in which the background signal is removed, based on the emission optical signal and the background signal.

12. The process monitoring system of claim 11, wherein the first and second inclined angles are determined to be changed with each other, according to the emission optical signal band and the background signal band.

13. An optical sensor module comprising:
a module receiving part configured to form a receiving space, an incident portion into which a light is incident being formed in a first side surface of the module receiving part;
a splitter part disposed in the receiving space, and having at least one splitter configured to split an incident light;
a transmission filter part having at least two transmission filters arranged along a direction perpendicular to a direction of the incident light, the transmission filters being configured to transmit predetermined signals of different bands; and
an optical detecting part having at least two optical detectors respectively arranged with the transmission filters, the optical detectors being configured to detect a light passing through the transmission filters.

14. The optical sensor module of claim 13, wherein the transmission filters are spaced apart from each other, a full width at half maximum (FWHM) of each of the transmission filters is 10 nm or less, and a size of each of the transmission filters is larger than that of each of the optical detectors.

15. The optical sensor module of claim 13, wherein the splitter part comprises:
a first splitter receiving the incident light; and
at least one additional splitter receiving a light split from the first splitter.

16. The optical sensor module of claim 15, wherein the first splitter is disposed at a first side of the module receiving part to be aligned with the incident light,
wherein the additional splitter is spaced apart from the first splitter by a predetermined distance and is arranged along an arranged direction of the transmission filters.

17. The optical sensor module of claim 16, wherein as the light is split and provided from the first splitter to the additional splitter, an amount of the light incident into each of the transmission filters is changed.

18. The optical sensor module of claim 13, wherein the first splitter is disposed at a center of the module receiving part to be arranged with the incident light,
wherein the additional splitter is spaced apart from the first splitter along a direction of the incident light, and at least two additional splitters are arranged to be perpendicular to the direction of the incident light.

19. The optical sensor module of claim 18, wherein the additional splitters are respectively arranged with the transmission filters, and an amount of the light incident into each of the transmission filters from each of the additional splitters is uniformly maintained.

20. A process monitoring system having the optical sensor module of claim 13,
wherein each of the transmission filters transmitting signals in different bands is configured to transmit an emission optical signal in an emission optical signal band and a background signal in a background signal band,
wherein the process monitoring system comprises a signal processor configured to calculate a pure emission optical signal in which the background signal is removed, based on the emission optical signal and the background signal.
